(19) United States
(12) Patent Application Publication
(10) Pub. No.: US 2007/0138605 A1
(43) Pub. Date: Jun. 21, 2007

(54) ADHESIVE SHEET, SEMICONDUCTOR DEVICE HAVING THE SAME, MULTI-STACKED PACKAGE HAVING THE SAME, AND METHODS OF MANUFACTURING A SEMICONDUCTOR DEVICE AND A MULTI-STACKED PACKAGE

(75) Inventors: Tae-Duk Nam, Chungcheongnam-do (KR); Bo-Seong Kim, Seoul (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggid-do (KR)

(21) Appl. No.: 11/613,881

(22) Filed: Dec. 20, 2006

(30) Foreign Application Priority Data
Dec. 20, 2005 (KR) 2005-126013

(51) Int. Cl. H01L 23/495

(52) U.S. Cl. 257/666

(57) ABSTRACT

A semiconductor device includes a semiconductor chip and an adhesive sheet adhered to a lower surface of the semiconductor chip, the adhesive sheet including a deformation prevention layer for suppressing deformation of the semiconductor chip. The adhesive sheet includes an adhesive layer, a base layer formed under the adhesive layer, and a deformation prevention layer interposed between the base layer and the adhesive layer, the deformation prevention layer suppressing deformation of the semiconductor chip. A deformation prevention sheet is further formed on a lower surface of the semiconductor chip. Methods of forming a semiconductor device and a multi-stacked package include adhesive sheets.

### CROSS-REFERENCE TO RELATED APPLICATIONS

This application claims priority under 35 USC § 119 to Korean Patent Application No. 2005-126013 filed on Dec. 20, 2005, the contents of which are herein incorporated by reference in their entirety.

### BACKGROUND

1. Field of the Invention

The invention relates to an adhesive sheet for a semiconductor chip, a semiconductor device having the adhesive sheet, a multi-stacked package including the semiconductor device, a method of manufacturing the semiconductor device and a method of manufacturing the multi-stacked package. More particularly, the invention relates to an adhesive sheet for adhering semiconductor chips to each other or adhering a semiconductor chip to a mounting board, a semiconductor device having the adhesive sheet, a multi-stacked package having a plurality of packages that are physically and electrically connected to each other using the adhesive sheet, a method of manufacturing the semiconductor device, and a method of manufacturing the multi-stacked package.

2. Description of the Related Art

In general, a semiconductor device may be manufactured by a fabrication process for fabricating a semiconductor chip including an integrated circuit on a silicon substrate, an electrical die sorting (EDS) process for inspecting electrical characteristics of the semiconductor chip, a packaging process for packaging the semiconductor chip into a chip package, to thereby protect the semiconductor chip, and a mounting process for mounting the chip package on a printed circuit board (PCB).

Recently, the semiconductor device has been developed to acquire a high performance and a high degree of integration. Since the packaging process technology may determine the size, the heat dissipation capacity, the electrical capabilities, the reliability, and the manufacturing cost of the semiconductor device, the packaging process technology may be required to be improved in order to achieve the semiconductor device having a high performance and a high degree of integration.

A packaging process technology impacts greatly on most characteristics of a semiconductor device such as a size, a heat dissipation capacity, an electric performance, a reliability and a cost, so that cutting-edge semiconductor devices having a high performance and a high degree of integration essentially require more elaborate packaging technologies.

A single inline package (STP) technology, a dual inline package (DIP) technology, a quad flat package (QFP) technology and a ball grid array (BGA) technology have been most widely used in the packaging process. Particularly, a chip scale package (CSP) technology, a multi-chip package (MCP) technology, a stacked chip-scale package (SCSP) technology and a wafer-level chip-scale package (WLCSP) technology have been recently preferred as the packaging process technologies so as to improve an efficiency of the mounting process for mounting the chip package on the PCB. Further, a wafer-level package (WLP) technology has been developed. According to the WLP technology, a process for manufacturing semiconductor chips on a wafer is performed and then a die-bonding process, a molding process, a trimming process and a marking process are sequentially carried out. The wafer including the chips is cut to manufacture a chip package.

A package process technology that has been recently favored is focused on reducing a thickness of a semiconductor device. Particularly, various research has been conducted for scaling down a thickness of a multi-stacked package (MSP) in which a plurality of semiconductor chips are vertically stacked on the substrate, because a thickness of a semiconductor device is decisively determined by a thickness of a MSP. In order to reduce the thickness of the MSP, there has been suggested a reduction of a thickness of the semiconductor chip. As the thickness of the semiconductor chip is mainly determined by a thickness of the substrate on which an integrated circuit is formed, intensive research has been conducted for reducing the thickness of the substrate so as to decrease the thickness of the MSP. As a result, the thickness of the semiconductor chip is now reduced to a degree of below about 100 μm.

However, a reduction in the thickness of the semiconductor chip usually causes a reduction in strength of the semiconductor chip, so that the semiconductor chip may be easily deformed by even a small external impact. The above-described deformation of the semiconductor chip may cause various problems in the semiconductor device. For example, the semiconductor chip may be mechanically separated from a mounting board, so that the semiconductor chip is not electrically connected to the mounting board. Further, an upper semiconductor chip may be separated from a lower semiconductor chip in the MSP, so that the lower and upper semiconductor chips are not electrically connected to each other in the MSP. Furthermore, the deformation of the semiconductor chip causes voids in the semiconductor device, thereby generating a malfunction of the semiconductor device.

FIG. 1 is a cross-sectional view illustrating a conventional semiconductor device.

Referring to FIG. 1, a semiconductor device 10 includes a semiconductor chip 11 and an adhesive sheet 30. The semiconductor chip 11 includes a silicon substrate 20 and an integrated circuit 15 formed on the silicon substrate 20. The adhesive sheet 30 is formed on a lower surface of the semiconductor chip 11.

The adhesive sheet 30 secures the semiconductor chip 11 to a mounting board (not shown). Alternatively, the adhesive sheet 30 secures the semiconductor chip 11 to another semiconductor chip (not shown).

The adhesive sheet 30 includes an adhesive layer 32, an ultraviolet layer 34 and a base layer 36, The ultraviolet layer 34 is formed on the base layer 36 and the adhesive layer 32 is formed on the ultraviolet layer 34.

An upper surface of the adhesive layer 32 is attached to a lower surface of the semiconductor chip 11. The ultraviolet layer 34 and the base layer 36 are separated from a lower surface of the adhesive layer 32 before the semiconductor chip 11 is attached to an object (not shown). The lower surface of the adhesive layer 32 is attached to the object to fix the semiconductor chip 11 to the object. That is, the semiconductor chip 11 is secured to the object using the adhesive layer 32 of the adhesive sheet 30.

The deformation of the semiconductor chip 11 may damage a semiconductor device (not shown) including the semiconductor chip 11 as well as the semiconductor chip 11. The semiconductor chip 11 is usually secured to an object such as a mounting board or other semiconductor chip mounted on the mounting board, and the object usually has rigidity greater than that of the semiconductor chip 11. Accordingly, when an external impact is applied to the semiconductor chip 11 attached to the object, the object is not deformed by the external impact even though the semiconductor chip 11 is deformed in accordance with the external impact, thereby separating the semiconductor chip 11 from the object. That is, an adhesive force applied between the adhesive layer 32 and the object or an adhesive force applied between the adhesive layer 32 and the semiconductor chip 11 is remarkably decreased due to the deformation of the semiconductor chip 11, and thus the semiconductor chip 11 is separated from the object. The smaller the thickness of the semiconductor chip 11, the more easily the semiconductor chip 11 is separated from the object.

The semiconductor chip 11 is required to be electrically connected to the object. However, when the semiconductor chip 11 is deformed, an adhesive reliability of the semiconductor chip 10 may be deteriorated thereby electrically disconnecting the semiconductor chip 11 from the object. Thus, the semiconductor chip may not accurately output or input electrical signals. As a result, to ensure an operational stability of the semiconductor chip 11 and the semiconductor device including the semiconductor chip 11 is difficult.

Over the years, the semiconductor device has been developed for having a high performance and a high degree of integration to increase commercial values of the semiconductor chip and the semiconductor device including the semiconductor chip. However, when the semiconductor chip and the semiconductor device are damaged, an economical or temporal loss may inevitably follow. Consequently, a semiconductor device and an MSP that ensure the operational stability of thin semiconductor chips by preventing deformation of the semiconductor chips are desired.

### SUMMARY

Example embodiments of the invention provide an adhesive sheet capable of suppressing deformation of a semiconductor chip and a semiconductor device capable of suppressing deformation of a semiconductor chip using the adhesive sheet. Example embodiments of the invention also provide a multi-stacked package capable of stably stacking multiple semiconductor chips. Other embodiments of the invention provide a method of manufacturing a semiconductor device capable of suppressing deformation of a semiconductor chip and a method of manufacturing a multi-stacked package capable of suppressing deformation of a semiconductor chip.

According to an example embodiment of the invention, an adhesive sheet includes an adhesive layer, which is to be formed on a semiconductor chip, a base layer formed under the adhesive layer, and a deformation prevention layer, which suppresses deformation of the semiconductor chip and is interposed between the base layer and the adhesive layer. Here, the deformation prevention layer includes a metal such as copper (Cu), gold (Au), silver (Ag) or a mixture thereof.

In an example embodiment of the invention, an adhesive sheet may further include an ultraviolet layer interposed between the deformation layer and base layer for separating the deformation layer from the base layer.

According to some example embodiments of the present invention, a semiconductor device includes a semiconductor chip and an adhesive sheet that is adhered to a lower surface of the semiconductor chip and includes a deformation prevention layer to suppress deformation of the semiconductor chip.

In an example embodiment of the present invention, a semiconductor device may further include a deformation prevention sheet that is adhered to the adhesive sheet and formed on the lower surface of the semiconductor chip, Here, the deformation prevention sheet includes a metal such as titanium (Ti), tungsten (W), copper (Cu) or a mixture thereof.

According to some example embodiment of the invention, a multi-stacked package includes a mounting substrate, a first semiconductor chip positioned on the mounting substrate, a second semiconductor chip positioned on the first semiconductor chip, adhesive sheets interposed between the mounting substrate and the first semiconductor chip, and between the first and second semiconductor chips, the adhesive sheets adhering the mounting substrate and the first and second semiconductor chips to each other, and each of the adhesive sheets including a deformation prevention layer for suppressing the first and second semiconductor chips from being deformed, conductive lines electrically connecting the first and second semiconductor chips to the mounting substrate, and a molding member formed on the mounting substrate, the molding member covering the first and second semiconductor chips and the conductive lines.

According to some example embodiments of the present invention, a lower surface of a semiconductor chip is polished and then a deformation prevention layer is formed on the polished lower surface of the semiconductor chip. An adhesive sheet is adhered to a lower surface of the deformation prevention layer and includes a deformation prevention layer for suppressing the semiconductor chip from being deformed. Here, the deformation prevention layer may be formed by a sputtering process.

In an example embodiment of the present invention, each of the adhesive sheets has a deformation prevention layer and is adhered to each of lower surfaces of a first semiconductor and a second semiconductor chips. The first and second semiconductor chips are attached to a mounting substrate. The first and second semiconductor chips are electrically connected to the mounting substrate. Then, a molding member is formed on the mounting substrate, to thereby protect the first and second semiconductor chips from an external impact.

According to the invention, an adhesive sheet having a deformation prevention layer and a deformation prevention sheet may be used to suppress a deformation of a semiconductor chip. Further, a heat in the semiconductor chip may be effectively dissipated. Thus, an adhesive reliability of the semiconductor chip may be increased and a reliable operation of a semiconductor apparatus may be ensured.

### BRIEF DESCRIPTION OF THE DRAWINGS

The above and other features and advantages of the invention will become readily apparent by reference to the following detailed description when considered in conjunction with the accompanying drawings wherein:

FIG. 1 is a cross-sectional view illustrating a conventional semiconductor apparatus;

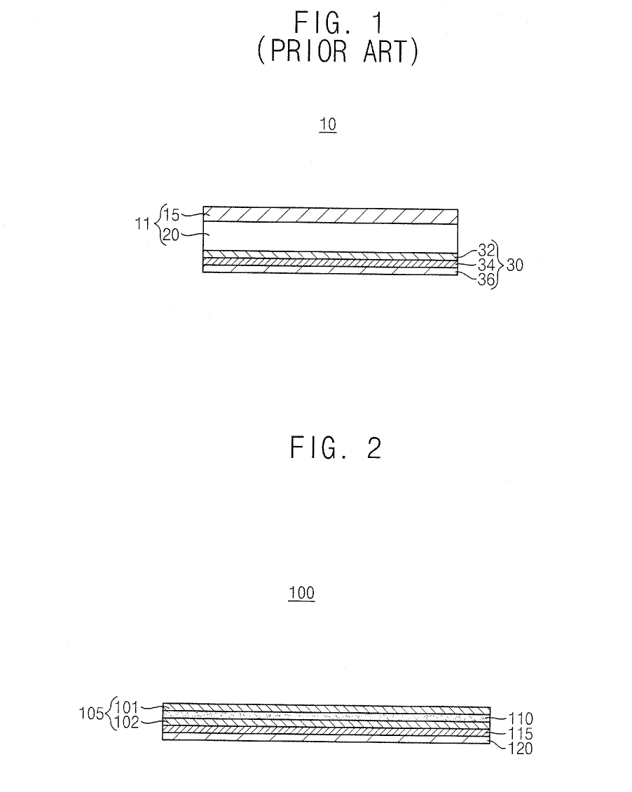

FIG. 2 is a cross-sectional view illustrating an adhesive sheet for a semiconductor package in accordance with an example embodiment of the invention;

FIG. 3 is a cross-sectional view illustrating a semiconductor device in accordance with an example embodiment of the invention;

FIGS. 4 to 7 are cross-sectional views illustrating a method of manufacturing a semiconductor device as shown in FIG. 3;

FIG. 8 is a cross-sectional view illustrating a multi-stacked package in accordance with an example embodiment of the invention; and

FIGS. 9 to 12 are cross-sectional views illustrating a method of manufacturing a multi-stacked package as shown in FIG. 8.

### DETAILED DESCRIPTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

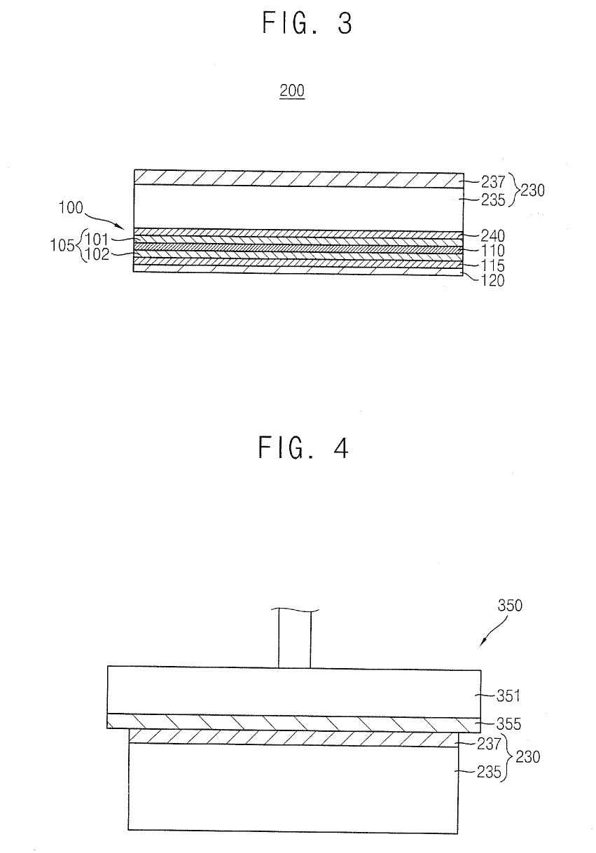

FIG. 2 is a cross-sectional view illustrating an adhesive sheet for a semiconductor package in accordance with an example embodiment of the present invention.

Referring to FIG. 2, an adhesive sheet 100 for a semiconductor package includes an adhesive layer 105, a deformation prevention layer 110, an ultraviolet layer 115 and a base layer 120.

The adhesive layer 105 includes a first adhesive film l 01 and a second adhesive film 102. The deformation prevention layer 110 is interposed between the first adhesive film 101 and the second adhesive film 102. The ultraviolet layer 115 is formed beneath the second adhesive film 102. The base layer 120 is formed beneath the ultraviolet layer 115. That is, the ultraviolet layer 115, the second adhesive film 102, the deformation prevention layer 110 and the first adhesive film 101 are sequentially formed on the base layer 120. Elements of the adhesive sheet 100 in the semiconductor package are described in detail as follows.

The first adhesive film 101 is positioned at a top position of the adhesive sheet 100 for the semiconductor package. The first adhesive film 101 may be adhered to a lower surface of a semiconductor chip (not shown), to thereby secure the adhesive sheet 100 to the semiconductor chip. The first adhesive film 101 may include acrylic resin, silicon resin, epoxy resin, polyamide resin, polyimide resin, fusible fluorine resins, bismaleimide triadin resin, etc. These may be used alone or in a combination thereof.

The deformation prevention layer 110 may include a material having a relatively low internal stress, a relatively high modulus and a relatively high rigidity. For example, the deformation prevention layer 110 includes a metal such as copper (Cu), gold (Au), silver (Ag) or a combination thereof. Alternatively, the deformation prevention layer 110 includes a composite such as a polymer.

The modulus is an elastic coefficient corresponding to a ratio of the stress to the deformation or a strain, so that the modulus is proportional to the rigidity. In general, a material having a high modulus has a high rigidity, whereas a material having a low modulus has a low rigidity. The modulus of the metal is well known to be substantially higher than that of the rubber.

Recently, because a semiconductor chip tends to have a small thickness, the semiconductor chip may be deformed by a relatively low external impact. However, when the deformation prevention layer 110 having a relatively high modulus is employed to the adhesive sheet 100, the semiconductor chip may be suppressed from being deformed by a relatively low external impact, even though the semiconductor chip may have a relatively small thickness.

The deformation prevention layer 110 is positioned at a lower portion of the adhesive sheet 100 so that the adhesive sheet 100 including the deformation prevention layer 110 has a rigidity greater than that of the adhesive sheet without the deformation prevention layer 110. Thus, the semiconductor chip may have an increased rigidity such that the semiconductor chip experiences a relatively less deformation, e.g., a torsion.

A thickness of the deformation prevention layer 110 may be determined in accordance with an overall thickness of the adhesive sheet 100, which increases due to the deformation prevention layer 110. For example, the deformation prevention layer 110 has a thickness below about 10 μm.

Although the second adhesive film 102 is initially formed on the ultraviolet layer 115 as shown in FIG. 2, the second adhesive film 102 is eventually formed on a mounting substrate or another semiconductor chip. That is, the ultraviolet layer 115 separates the base layer 120 from the second adhesive film 102. For example, when an ultraviolet ray is irradiated to the ultraviolet layer 115, an adhesive force between the ultraviolet layer 115 and the second adhesive film 102 is reduced, so that the base layer 120 and the ultraviolet layer 115 may be easily separated form the second adhesive film 102.

The second adhesive film 102 separated from the ultraviolet layer 115 is then adhered to the mounting substrate or another semiconductor chip to secure the semiconductor chip to the mounting substrate or another semiconductor chip.

The second adhesive film 102 may include an acrylic resin, a silicon resin, an epoxy resin, a polyamide resin, a polyimide resin, a fusible fluorine resin, a bismaleimide triadin resin, etc. These may be used alone or in a combination thereof The second adhesive film 102 may have a material substantially the same as that of the first adhesive film 101.

The base layer 120 and the ultraviolet layer 115 are well known to those skilled in the art. Thus, any further descriptions of the base layer 120 and the ultraviolet layer 115 are omitted.

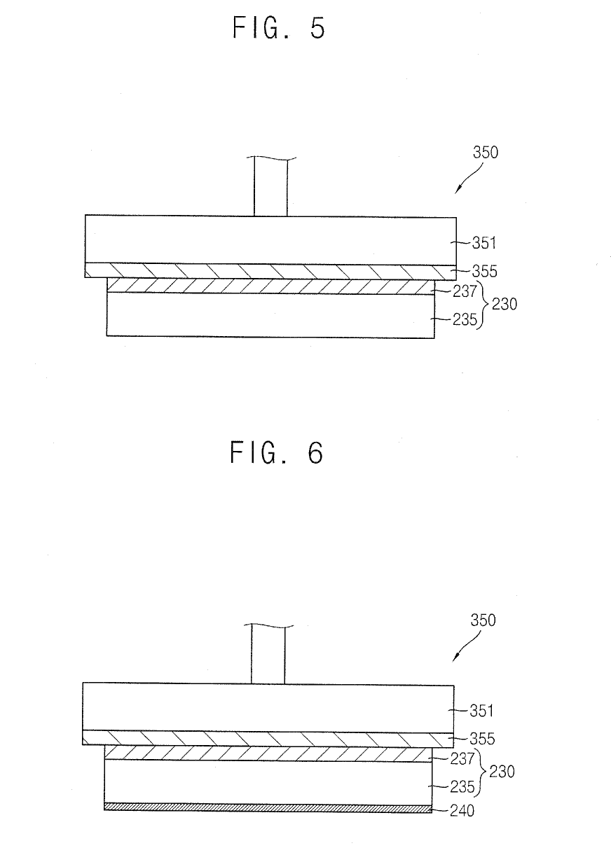

FIG. 3 is a cross-sectional view illustrating a semiconductor device in accordance with an example embodiment of the present invention.

Referring to FIG. 3, a semiconductor device 200 in accordance with an example embodiment of the invention includes a semiconductor chip 230 and an adhesive sheet 100 for a semiconductor package. The adhesive sheet 100 of the semiconductor device 200 in FIG. 3 is substantially the same as the adhesive sheet described in detail with reference to FIG. 2, and the same reference numerals in FIG. 3 denote the same elements in FIG. 2, so that the detailed descriptions of the same elements will be omitted.

The semiconductor chip 230 includes a semiconductor substrate 235 and integrated circuits 237 formed on the semiconductor substrate 235. The semiconductor substrate 235 may include a silicon substrate and a silicon-on-insulator (SOI) substrate. The integrated circuits 237 are formed on the semiconductor substrate 235 through a series of semiconductor manufacturing processes.

In an example embodiment of the invention, the semiconductor device 200 may further include a deformation prevention sheet 240 formed on a lower surface of the semiconductor chip 230. For example, the deformation prevention sheet 240 is formed on a lower surface of the semiconductor substrate 235.

The deformation prevention sheet 240 may increase the rigidity of the semiconductor chip 230 because the deformation prevention sheet 240 includes a material having a relatively high modulus and rigidity. For example, the deformation prevention sheet 240 has a material having a modulus and a rigidity greater than those of the substrate 235. Further, the deformation prevention sheet 240 may include a material having characteristics such as a good heat dissipation and a relatively high rigidity. For example, the deformation prevention sheet 240 includes titanium (Ti), tungsten (W), copper (Cu) or a mixture thereof.

The deformation prevention sheet 240 may have a multi-layered structure. For example, the deformation prevention sheet 240 has a double-layered structure including two metal layers. For example, the deformation prevention sheet 240 has a copper layer and a tungsten layer stacked on the copper layer.

A thickness of the deformation prevention sheet 240 may be determined in accordance with an overall thickness of the semiconductor device 200. For example, the deformation prevention sheet 240 has a thickness of below about 10 μm.

A heat of the semiconductor chip 230 may be sufficiently dissipated through the deformation prevention sheet 240, to thereby improve a thermal stability of the semiconductor chip 230.

However, the deformation prevention sheet 240 is selectively formed on the semiconductor chip 230 in various manners, and a method of forming the deformation prevention sheet 240 will be described below.

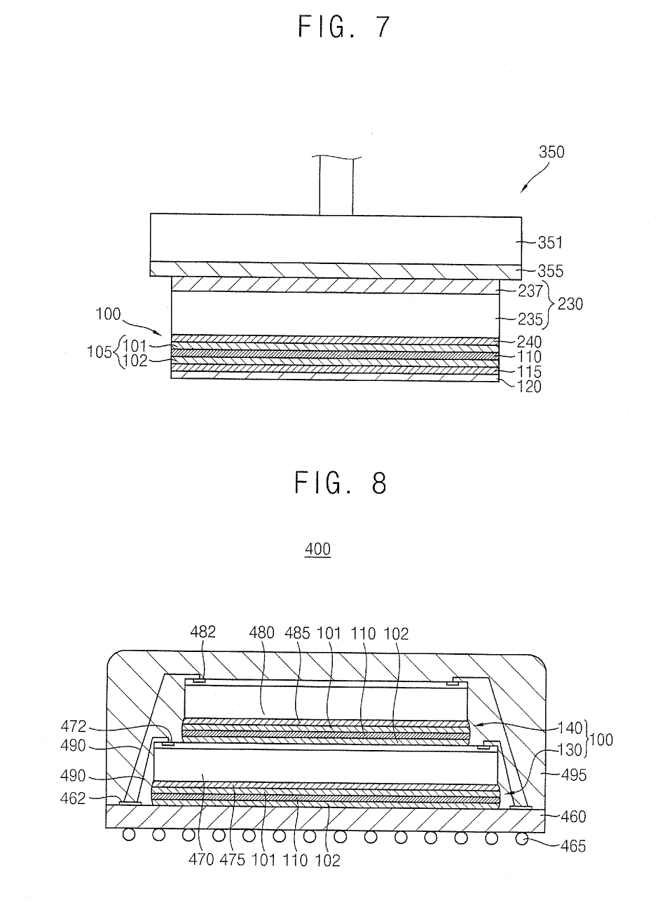

FIGS. 4 to 7 are cross-sectional views illustrating processing steps for a method of manufacturing a semiconductor device shown in FIG. 3.

Referring to FIG. 4, a semiconductor chip 230 is provided. The semiconductor chip 230 includes a semiconductor substrate 235 and integrated circuits 237 that are formed on the semiconductor substrate 235. Then, a supporting member 350 is adhered to the semiconductor chip 230.

The supporting member 350 holds the semiconductor chip 230. The supporting member 350 includes a glass holder 351 and an ultraviolet layer 355 formed on the glass holder 351. An adhesive sheet (not shown) is formed on the ultraviolet layer 355 to adhere the semiconductor chip 230 to the supporting member 350.

Referring to FIG. 5, a lower surface of the semiconductor chip 230, i.e., a lower surface of the semiconductor substrate 235, which is adhered to the supporting member 350, is polished by a polishing process. For example, the polishing process includes an etch-back process, a chemical mechanical polishing (CMP) process or a combination process of etch-back and CMP. In an example embodiment of the present invention, the polishing process is performed until the semiconductor chip 230 has a thickness of about 100 μm.

When the semiconductor chip 230 is polished, the integrated circuits 237 may not be damaged at all, because the ultraviolet layer 355 adhered to the integrated circuits 237 protects the integrated circuits 237 from external impacts.

Referring to FIG. 6, a deformation prevention sheet 240 is formed on the polished lower surface of the semiconductor chip 230. The deformation prevention sheet 240 may be formed by a deposition process such as a physical vapor deposition (PVD) process and a chemical vapor deposition (CVD) process. For example, the deformation prevention sheet 240 is formed on the polished lower surface of the semiconductor chip 230 by a sputtering process.

The deformation prevention sheet 240 may be formed to have a double-layered structure including two metal layers. For example, the deformation prevention sheet 240 has a titanium tungsten (TiW) layer formed on the lower surface of the semiconductor chip 230 and a copper (Cu) layer formed on a lower surface of the titanium tungsten (TiW) layer. Then, a tape mounting process may be further carried out.

Referring to FIG. 7, an adhesive sheet 100 is adhered to the deformation prevention sheet 240, which is formed on the lower surface of the semiconductor chip 230. The adhesive sheet 100 is adhered to the deformation prevention sheet 240. Particularly, the adhesive sheet 100 is secured to the deformation prevention sheet 240 by a thermal compression process. That is, the adhesive sheet 100 is heated and simultaneously pressed onto the semiconductor chip 230, to thereby secure a first adhesive film 101 of the adhesive sheet 100 to a lower surface of the deformation prevention sheet 240.

The supporting member 350 is separated from the semiconductor chip 230 to which the adhesive sheet 100 is adhered, thereby completing the semiconductor device 200 shown in FIG. 3. In an example embodiment of the present invention, the supporting member 350 is easily separated from the semiconductor chip 230 by irradiating an ultraviolet ray to the ultraviolet layer 355.

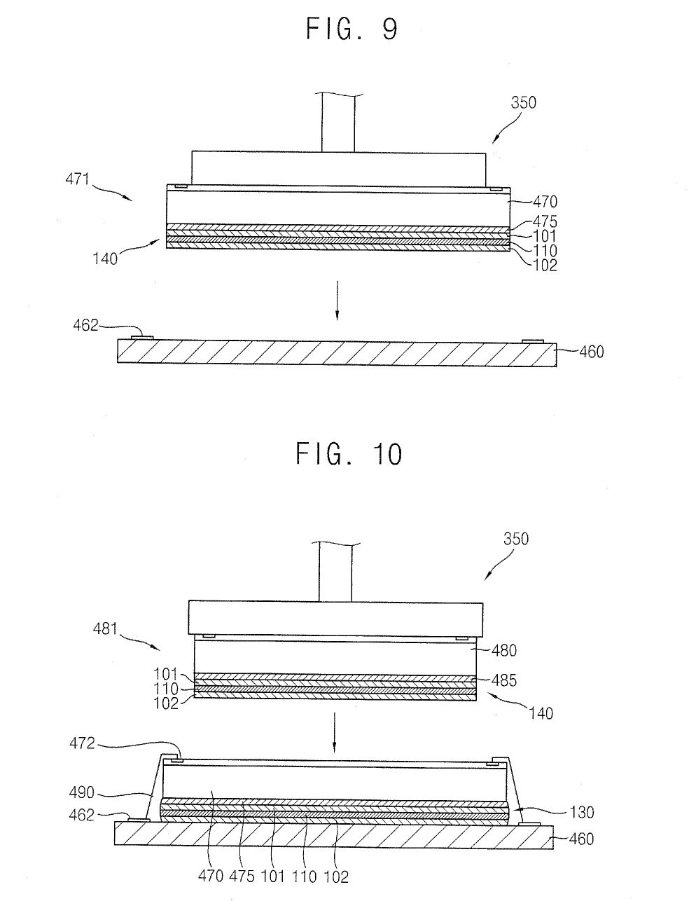

FIG. 8 is a cross-sectional view illustrating a multi-stacked package in accordance with an example embodiment of the present invention.

Referring to FIG. 8, a multi-stacked package 400 in accordance with an example embodiment of the invention includes a mounting substrate 460, a first semiconductor chip 470, a second semiconductor chip 480, adhesive sheets 100 for a semiconductor package, conductive lines 490 and a molding member 495. Each of the adhesive sheets 100 in the multi-stacked package 400 in FIG. 10 is substantially the same as those described in detail with reference to FIG. 2 except that the ultraviolet layer 115 and the base layer 120 are removed from the adhesive sheet 100. Hence, the same reference numerals of the adhesive sheets in FIG. 10 denote the same elements of the adhesive sheets in FIG. 2, and the detailed descriptions of the same elements will be omitted.

The first semiconductor chip 470 and the second semiconductor chip 480 are sequentially stacked on the mounting substrate 460. The adhesive sheets 100 include a first adhesive sheet 130 and a second adhesive sheet 140. The first adhesive sheet 130 is interposed between the mounting substrate 460 and the first semiconductor chip 470. The second adhesive sheet 140 is interposed between the first semiconductor chip 470 and the second semiconductor chip 480. Each of the first and the second adhesive sheets 130 and 140 includes a deformation prevention layer 110. Elements of the multi-stacked package 400 will be described in detail as follows.

The mounting substrate 460 includes conductive terminals 465 and connection pads 462.

The conductive terminals 465 are formed on a lower surface of the mounting substrate 460. The conductive terminals 465 output electrical signals from the first and second semiconductor chips 470 and 480 or transmit electrical signals to the first and second semiconductor chips 470 and 480. The conductive terminals 465 may include solder, solder balls and/or lead wires.

The connection pads 462 are formed on an upper surface of the mounting substrate 460. The connection pads 462 are electrically connected to the first and second semiconductor chips 470 and 480. For example, the connection pads 462 may be electrically connected to the conductive terminals 465 via circuit lines (not shown) formed on the mounting substrate 460.

In one example embodiment of the present invention, the first adhesive sheet 130 is adhered to the first semiconductor chip 470, and then the first semiconductor chip 470 is positioned on the mounting substrate 460. In another example embodiment of the present invention, the first adhesive sheet 130 is adhered to the mounting substrate 460, and then the first semiconductor chip 470 is adhered to the first adhesive sheet 130. A first adhesive layer 101 of the first adhesive sheet 130 is adhered to a lower surface of the first semiconductor chip 470. A second adhesive layer 102 of the first adhesive sheet 130 is adhered to an upper surface of the mounting substrate 460.

When the first adhesive sheet 130 is adhered to the mounting substrate 460 and then the first semiconductor chip 470 is adhered to the first adhesive sheet 130, the first adhesive sheet 130 may be patterned in accordance with a width of the first semiconductor chip 470. Further, the first adhesive sheet 130 may be positioned on the mounting substrate 460 in such a structure that the first adhesive sheet 130 and the conductive lines 490 are not overlapped with each other.

The first adhesive sheet 130 may include an adhesive agent such as a paste.

The multi-stacked package 400 may further include a first deformation prevention sheet 475. The first deformation prevention sheet 475 is formed on the lower surface of the first conductive chip 470. The first deformation prevention sheet 475 increases a rigidity of the first semiconductor chip 470. The first deformation prevention sheet 475 may include a material having a high modulus and rigidity. For example, the first deformation prevention sheet 475 includes a metal such as titanium (Ti), tungsten (W), copper (Cu) or a combination thereof. Further, the first deformation prevention sheet 475 may effectively dissipate heat from the first semiconductor chip 470 onto the mounting substrate 460.

The first semiconductor chip 470 is electrically connected to the mounting substrate 460. Particularly, a bonding pad 472 of the first semiconductor chip 470 and the connection pad 462 of the mounting substrate 460 are electrically connected to each other through the conductive lines 490 such as bonding wires.

The second semiconductor chip 480 is positioned on the first semiconductor chip 470 electrically connected to the mounting substrate 460. The first adhesive film 101 of the second adhesive sheet 140 is adhered to a lower surface of the second semiconductor chip 480, and the second adhesive film 102 of the second adhesive sheet 140 is adhered to an upper surface of the first semiconductor chip 470.

In one example embodiment of the present invention, the second adhesive sheet 140 is adhered to the second semiconductor chip 480, and then the second semiconductor chip 480 is positioned on the first semiconductor chip 470. In another example embodiment of the present invention, the second adhesive sheet 140 is adhered to the first semiconductor chip 470, and then the second semiconductor chip 480 is positioned on the second adhesive sheet 140. A size of the second semiconductor chip 480 may be substantially the same as or different from that of the first mounting substrate 460. The multi-stacked package 400 may further include a second deformation prevention sheet 485. The second deformation prevention sheet 485 is formed on the lower surface of the second conductive chip 480. The second deformation prevention sheet 485 increases a rigidity of the second semiconductor chip 480. Further, the second deformation prevention sheet 485 may dissipate heat from the second semiconductor chip 480.

The second semiconductor chip 480 is electrically connected to the mounting substrate 460. Particularly, a bonding pad 482, which is formed on the second semiconductor chip 480, and the connection pad 462, which is formed on the mounting substrate 460, are electrically connected to each other through the conductive lines 490 such as bonding wires. Further, the second semiconductor chip 480 may be electrically connected to the mounting substrate 460.

The molding member 495 protects the first and second semiconductor chips 470 and 480, which are stacked on the mounting substrate 460, as well as the conductive lines 490 from an external impact. The molding member 495 may have a sufficient height to cover the first and second semiconductor chips 470 and 480 as well as the conductive lines 490. Thus, the molding member 495 may prevent the first and second semiconductor chips 470 and 480, and the conductive lines 490 from getting damaged.

According to an example embodiment of the present invention, the first and second semiconductor chips 470 and 480 may have increased rigidities due to the first and second deformation prevention sheets 475 and 485, and the first and second adhesive sheets 130 and 140. When an environmental factor such as a temperature or a humidity changes extremely or an external impact is applied to the multi-stacked package, the first and second semiconductor chips 470 and 480 may be suppressed from being deformed and being electrically exposed to the mounting substrate 460. As a result, the multi-stacked package 400 may have an improved mechanical and electrical characteristic.

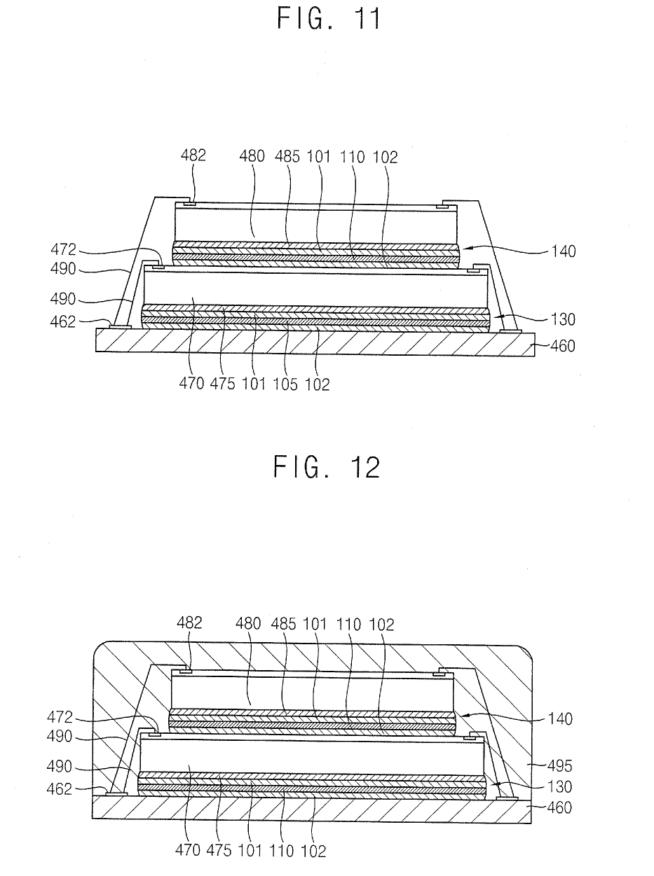

FIGS. 9 to 12 are cross-sectional views illustrating a method of manufacturing a multi-stacked package as shown in FIG. 8.

Referring to FIG. 9, a first adhesive sheet 130 is provided. Particularly, the first adhesive sheet 130 is formed to include an adhesive layer including a first adhesive film 101 and a second adhesive film 102, and a deformation prevention layer 110 interposed between the first and second adhesive films 101 and 102.

A first semiconductor chip 470 is provided. The first semiconductor chip 470 may be formed to include a substrate (not shown) and integrated circuits (not shown) formed on the substrate.

In an example embodiment of the present invention, a polishing process such as a CMP process is performed on the lower surface of the first semiconductor chip 470. The first semiconductor chip 470 may be held to a supporting member 350 as shown in FIG. 4 during the polishing process. Then, a deposition process is performed on the lower surface of the first semiconductor chip 470, thereby forming the first deformation prevention sheet 475 on the lower surface of the semiconductor chip 470. For example, a sputtering process may be used for forming the first deformation prevention sheet 475.

Then, a first adhesive sheet 130 and the first deformation prevention sheet 475 are secured to a lower surface of the first semiconductor chip 470 to provide a first semiconductor device 471.

While the example embodiment discusses the first semiconductor device 471 including the first deformation prevention sheet 475, the first deformation prevention sheet 475 may be omitted depending on a processing condition as known to those skilled in the art.

Thereafter, the first semiconductor device 471 is positioned over the mounting substrate 460. A second adhesive film 102 of the first adhesive sheet 130, which is adhered to the lower surface of the first semiconductor chip 470, is exposed. For example, an ultraviolet ray is irradiated to the first adhesive sheet 130 to separate the ultraviolet layer 115 and the base layer 120 (see FIG. 2) from the second adhesive film 102, thereby exposing the second adhesive film 102.

In one example embodiment, the first semiconductor chip 470 is secured to the mounting substrate 460 by a thermal compression process. For example, the first adhesive sheet 130 is heated and simultaneously pressed onto the mounting substrate 460 to secure the first semiconductor chip 470 to the mounting substrate 460.

In another example embodiment of the present invention, the first adhesive sheet 130 includes an adhesive agent such as a paste. Particularly, the adhesive agent is formed on the upper surface of the mounting substrate 460, and the first semiconductor chip 470 is pressed onto the mounting substrate 460, thereby securing the first semiconductor chip 470 to the mounting substrate 460.

Referring to FIG. 10, the first semiconductor chip 470 and the mounting substrate 460 are electrically connected to each other. The first semiconductor chip 470 and the mounting substrate 460 may be electrically connected by a bonding wire process. For example, the boding pad 472, which is formed on the first semiconductor chip 470, and the connection pad 462, which is formed on the mounting substrate 460, are electrically connected to each other using the conductive lines 490.

A second semiconductor chip 480 is provided. The second semiconductor chip 480 may be formed to include a substrate (not shown) and integrated circuits (not shown) formed on the substrate.

In an example embodiment, a polishing process such as a CMP process is performed on the lower surface of the second semiconductor chip 480. The second semiconductor chip 480 may be held to a supporting member 350 in FIG. 4 during the polishing process. Then, a deposition process is performed on the lower surface of the second semiconductor chip 480, thereby forming the second deformation prevention sheet 485 on the lower surface of the second semiconductor chip 480. For example, a sputtering process may be used for forming the second deformation prevention sheet 485.

Then, a second adhesive sheet 140 and a second deformation prevention sheet 485 are secured to a lower surface of the second semiconductor chip 480 to provide a second semiconductor device 481.

While the present embodiment discusses the second semiconductor device 481 including the second deformation prevention sheet 485, the second deformation prevention sheet 485 may be omitted depending on a processing condition as known to those skilled in the art.

The first and second semiconductor devices 471 and 481 may be simultaneously prepared.

The second semiconductor device 481 is positioned over the first semiconductor device 471, which is secured to the mounting substrate 460. A second adhesive film 102, which is included in the second adhesive sheet 140 adhered to the lower surface of the second semiconductor chip 480, is exposed. For example, an ultraviolet ray is irradiated to the second adhesive sheet 140 to separate the ultraviolet layer 115 and the base layer 120 from the second adhesive film 102. Thus, the second adhesive film 102 is exposed.

Referring to FIG. 11, the second semiconductor chip 480 is secured to the first semiconductor chip 470. For example, the second adhesive sheet 140 is heated to secure the second semiconductor chip 480 to the first semiconductor chip 470.

The second semiconductor chip 480 and the mounting substrate 460 are electrically connected to each other. For example, the second semiconductor chip 480 and the mounting substrate 460 are electrically connected by a bonding wire process. In an example embodiment of the present invention, a bonding pad 482 and a connection pad 462 of the mounting substrate 460 are electrically connected to each other through the conductive lines 490.

Referring to FIG. 12, a molding member 495 is formed on the mounting substrate 460 to cover the first and second semiconductor chips 470 and 480 as well as the conductive lines 490. The molding member 495 may be formed by an encapsulation process. The molding member 495 may protect the first and second semiconductor chips 470 and 480 as well as the conductive lines 490 from getting damaged. Since a process of forming the molding member 495 is a well-known process, any further description of the process is omitted. However, those skilled in the art will easily acknowledge the process of forming the molding member 495.

Referring again to FIG. 8, the conductive terminals 465 are formed on a lower surface of the mounting substrate 460. The conductive terminals 465 output electrical signals from the first and second semiconductor chips 470 and 480 or transmit electrical signals to the first and second semiconductor chips 470 and 480. The conductive terminals 465 may correspond to external terminals, which are electrically connected to an external device.

When the multi-stacked package 400 is manufactured, deformation such as a torsion may not occur to the first and second semiconductor chips 470 and 480. Further, after the first and second semiconductor chips 470 and 480 are sealed, the first and second semiconductor chips 470 and 480 may neither be separated from nor electrically exposed to the mounting substrate 460. Further, the first and second semiconductor chips 470 and 480 may have an improved heat dissipation characteristic. Thus, the multi-stacked package 400 may have an improved operational reliability.

The multi-stacked package 400 including two semiconductor chips 470 and 480 and the method of forming the multi-stacked package 400 are described above. However, the invention may be applied to a multi-stacked package including no less than three semiconductor chips. That is, in order to prevent deformation of the semiconductor chip and to improve a heat dissipation characteristic, the technology to form an adhesive member having a relatively high rigidity on the semiconductor chip may be within the scope of the present invention.

According to the present invention, an adhesive sheet having a relatively high rigidity is formed on the semiconductor chip such that a rigidity of a semiconductor chip increases to suppress a deformation of the semiconductor chip. Thus, an adhesive reliability of the semiconductor chip may be increased. As a result, a reliable semiconductor apparatus may be manufactured.

Having described the preferred embodiments of the present invention, it is noted that modifications and variations can be made by persons skilled in the art in light of the above teachings. It is therefore to be understood that changes may be made in the particular embodiment of the invention disclosed which is within the scope and the spirit of the invention outlined by the appended claims.

What is claimed is:

1. An adhesive sheet comprising:
an adhesive layer mountable on a lower surface of a semiconductor chip;
a base layer on a lower surface of the adhesive layer; and
a deformation prevention layer interposed between the base layer and the adhesive layer, the deformation prevention layer adapted to suppress deformation of the semiconductor chip.

2. The adhesive sheet of claim 1, wherein the deformation prevention layer comprises a material with a modulus and a rigidity greater than those of the semiconductor chip.

3. The adhesive sheet of claim 2, wherein the deformation prevention layer comprises a metal.

4. The adhesive sheet of claim 3, wherein the metal includes at least any one selected from the group consisting of copper (Cu), gold (Au), silver (Ag) and a combination thereof.

5. The adhesive sheet of claim 1, wherein the deformation prevention layer has a thickness no more than about 10 μm.

6. The adhesive sheet of claim 1, further comprising an ultraviolet layer interposed between the deformation prevention layer and the base layer for separating the deformation prevention layer from the base layer.

7. The adhesive sheet of claim 1, further comprising another adhesive layer interposed between the deformation prevention layer and the base layer.

8. The adhesive sheet of claim 1, further comprising a deformation prevention sheet interposed between the adhesive layer and the lower surface of the semiconductor chip.

9. A semiconductor device comprising:
a semiconductor chip; and
an adhesive sheet adhered to a lower surface of the semiconductor chip, the adhesive sheet including a deformation prevention layer for suppressing a deformation of the semiconductor chip.

10. The semiconductor device of claim 9, further comprising a deformation prevention sheet formed on the lower surface of the semiconductor chip, the deformation prevention sheet being adhered to the adhesive sheet.

11. The semiconductor device of claim 10, wherein the deformation prevention sheet includes a metal.

12. The semiconductor device of claim 11, wherein the metal includes at least any one selected from the group consisting of titanium (Ti), tungsten (W) and copper (Cu).

13. The semiconductor device of claim 9, wherein the adhesive sheet further comprises a first adhesive layer interposed between the deformation prevention layer and the lower surface of the semiconductor chip.

14. The semiconductor device of claim 13, wherein the adhesive sheet further comprises a second adhesive layer adhered to a lower surface of the deformation prevention layer.

15. The semiconductor device of claim 9, wherein the thickness of the deformation prevention layer is no more than about 10 □m.

16. A multi-stacked package comprising:
a mounting substrate;
a first semiconductor chip positioned on the mounting substrate;
a second semiconductor chip positioned on the first semiconductor chip;
adhesive sheets interposed between the mounting substrate and the first semiconductor chip and between the first and second semiconductor chips, the adhesive sheets adhering the mounting substrate and the first and second semiconductor chips to each other, and each of the adhesive sheets including a deformation prevention layer for suppressing the first and second semiconductor chips from being deformed;
conductive lines electrically connecting the first and second semiconductor chips to the mounting substrate; and
a molding member formed on the mounting substrate, the molding member covering the first and second semiconductor chips and the conductive lines.

17. The multi-stacked package of claim 16, further comprising deformation prevention sheets formed on lower surfaces of the first and second semiconductor chips, respectively.

18. The multi-stacked package of claim 16, wherein each of the adhesive sheets further comprises:
a first adhesive layer adhered to an upper surface of the deformation prevention layer; and
a second adhesive layer adhered to a lower surface of the deformation prevention layer.

19. The multi-stacked package of claim 16, further comprising:
bonding pads disposed on the first semiconductor chip and the second semiconductor chip;
connection pads disposed on the mounting substrate and electrically connected to the bonding pads by the conductive lines; and
conductive terminals disposed on a lower surface of the mounting substrate.

20. A method of manufacturing a semiconductor device, comprising:
polishing a lower surface of a semiconductor chip;
forming a deformation prevention sheet on the polished lower surface of the semiconductor chip; and
adhering an adhesive sheet to a lower surface of the deformation prevention sheet, the adhesive sheet including a deformation prevention layer for suppressing the semiconductor chip from being deformed.

21. The method of claim 20, wherein forming the deformation prevention sheet comprises a sputtering process.

22. The method of claim 20, wherein the deformation prevention sheet comprises: a copper layer adhered to the lower surface of the semiconductor chip; and a tungsten layer adhered to the copper layer.

23. The method of claim 20, wherein the deformation prevention sheet comprises a material having a relatively high modulus and a relatively high rigidity as compared to the semiconductor chip.

24. The method of claim 20, further comprising heating the adhesive sheet that is attached to the semiconductor chip.

25. A method of manufacturing a multi-stacked package, comprising:
adhering adhesive sheets to lower surfaces of a first semiconductor chip and a second semiconductor chip, the adhesive sheets each including a deformation prevention layer;
attaching the first semiconductor chip to a mounting substrate;
attaching the second semiconductor chip to the first semiconductor chip;
electrically connecting the first and second semiconductor chips to the mounting substrate; and
forming a molding member on the mounting substrate, the molding member protecting the first and second semiconductor chips from an external impact.

26. The method of claim 25, further comprising forming deformation prevention sheets on the lower surfaces of the first and second semiconductor chips.

27. The method of claim 25, further comprising heating each of the adhesive sheets that are attached to the first and second semiconductor chips.

28. A method of manufacturing a multi-stacked package, comprising:
providing a first semiconductor chip and a second semiconductor chip;
adhering a first adhesive sheet to a lower surface of the first semiconductor chip;
adhering a second adhesive sheet to an upper surface of the first semiconductor chip;
adhering the second semiconductor chip to a top surface of the second adhesive sheet, wherein the first adhesive sheet and the second adhesive sheet each comprise a deformation prevention layer.

29. The method of claim 28, further comprising forming a deformation prevention sheet on the lower surfaces of the first semiconductor chip and the second semiconductor chip before adhering the first adhesive sheet.

30. The method of claim 29, wherein the deformation prevention sheet comprises a copper layer and a tungsten layer.

31. The method of claim 29, wherein the thickness of the deformation prevention sheet is no more than about 10 □m.

32. The method of claim 29, wherein forming the deformation prevention sheet comprises a sputtering process.

33. The method of claim 28, further comprising adhering the first adhesive sheet to an upper surface of a mounting substrate.

34. The method of claim 33, further comprising:
electrically connecting the first semiconductor chip and the second semiconductor chip to the mounting substrate;
forming a molding member on the mounting substrate, the first semiconductor chip and the second semiconductor chip; and
forming conductive terminals on a lower surface of the mounting substrate.

35. The method of claim 34 wherein electrically connecting the first semiconductor chip and the second semiconductor chip to the mounting substrate comprises electrically connecting bonding pads on the first and second semiconductor chips to connection pads on the mounting substrate.

36. The method of claim 28, wherein the first adhesive sheet and the second adhesive sheet each comprise:
a first adhesive layer adhered to an upper surface of the deformation prevention layer; and
a second adhesive layer adhered to a lower surface of the deformation prevention layer.

37. The method of claim 28, further comprising removing a base layer from the second adhesive sheet before adhering the second semiconductor chip to a top surface of the second adhesive sheet.

38. The method of claim 37, wherein removing the base layer comprises irradiating the second adhesive sheet with UV radiation.

39. The method of claim 28, wherein the deformation prevention layers comprise one of copper, gold, and silver.
